(19) United States
(12) Patent Application Publication
(10) Pub. No.: US 2007/0215278 A1
(43) Pub. Date: Sep. 20, 2007

(54) Plasma etching apparatus and method for forming inner wall of plasma processing chamber

(76) Inventors: Muneo Furuse, Kudamatsu (JP); Masanori Kadotani, Kudamatsu (JP); Katsuji Matano, Kudamatsu (JP); Tadayoshi Kawaguchi, Kudamatsu (JP); Masatsugu Arai, Kasumigaura (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/367,597

(22) Filed: Mar. 6, 2006

(51) Int. Cl. H01L 21/306

(52) U.S. Cl. 156/345.1; 156/914

(57) ABSTRACT

A plasma etching apparatus is provided which can prevent corrosion of an aluminum substrate constituting an etching processing chamber or an inside component thereof, thereby avoiding a reduction in productivity due to scattering of a sprayed coating. In the plasma etching apparatus, an anodic oxide film is disposed between a ceramic sprayed coating with excellent resistance to plasma, and the etching processing chamber and the inside component thereof made of aluminum alloy. The anodic oxide film has a thickness of 5 μm or less to have heat resistance.

### FIELD OF THE INVENTION

The present invention relates to a plasma etching apparatus, and a method for forming an inner wall of a plasma processing chamber. More particularly, the invention is directed to a plasma etching apparatus using a halogen-based gas as a process gas, and a method for forming an inner wall of a plasma processing chamber in the same.

### BACKGROUND OF THE INVENTION

In a manufacturing process of a semiconductor, a liquid crystal device, or the like, process gases, including a fluoride, such as BF₃ or NF₃, a chloride, such as BCl₃ or SnCl₄, a bromide such as HBr, and Cl₂, may often be used in a processing vessel. In this case, there may arise a problem that an inside member of the processing vessel is subjected to significant corrosion and wear.

For example, it is well known that materials used for the inside members of the plasma processing vessel in a semiconductor production unit include metal material such as Al and Al alloy, an anodic oxide film made of Al, a sprayed coating such as a boron carbide, a sinter coating such as Al₂O₃ or Si₃N₄, and a polymer coating such as a fluororesin or an epoxy resin, which cover the surface of the metal material. As is known, these materials, when coming in contact with a strongly corrosive halogen ion, may be subjected to chemical damage or erosion damage by fine particles such as SiO₂ or Si₃N₄, and ions activated by a plasma.

In particular, in an etching process using a halogen compound, a plasma is often used in order to further activate the reaction. Under such a condition of use of the plasma, the halogen compound is dissociated into atomic elements, such as F, Cl, or Br, having high corrosion properties. If particulate solid matter, such as SiO₂, Si₃N₄, Si, or W, exists together with the halogen compound in the environment, the members or materials constituting components employed in the plasma processing vessel and the other processing vessel are subjected to chemical corrosion, and to erosion damage due to the fine particles, that is, are strongly subjected to the so-called erosion-corrosion damage.

Furthermore, under the environment in which the plasma is activated within the etching processing chamber, even inert gases, such as Ar, with no corrosion properties, may be ionized and strongly come into collision with a solid surface (that is, may cause a phenomenon called “ion bombardment”). It is known that in this case, various members disposed within the plasma processing vessel can be subjected to further serious damage.

In a conventional plasma etching apparatus, in order to improve resistance to plasma, it is known that an inside member within the plasma processing vessel is coated with a sprayed coating made of Y₂O₃ having a porosity of 5 to 10%, as disclosed in JP-A 164354/2001.

JP-A166043/2003 discloses a method of fabricating a member having excellent resistance to plasma, which involves forming an alumite layer as a barrier film on a surface of a substrate made of aluminum, and further forming a YAG film on the layer by detonation flame spraying.

Also, JP-A225745/2005 discloses a member having excellent resistance to plasma which comprises the Y₂O₃ or YAG film thermal-sprayed on an alumina substrate, an average surface roughness Ra of a part of the alumina substrate which is to be thermal-sprayed being not less than 5 μm nor more than 15 μm.

In the method as disclosed in JP-A 164354/2001, since the surface of the processing vessel which will come in contact with the plasma is coated with the sprayed coating made of Y₂O₃, the damage due to the plasma is expected to be reduced. Also, in this method, an undercoat of 50 to 500 μm in thickness is provided between the sprayed coating and the substrate for covering the surface of the substrate. The undercoat is made of Ni and Ni alloy, W and W alloy, Mo and Mo alloy, and Ti and Ti alloy. However, the surface roughness of the substrate to be covered with the sprayed coating and the undercoat was not taken into consideration sufficiently. Actually, when the surface of the substrate is roughen by blast processing or the like, and then is coated with a metal film of 50 to 500 μm in thickness, the roughness of the outermost surface is smaller than expected. Alternatively, when the surface of the substrate of interest for thermal spraying is coated with the metal film, and then subjected to the blast processing, the metal coating or film may be flaked off, which makes it difficult lo to ensure the toughness.

In these examples disclosed in the above-mentioned documents, the formation of the sprayed coating made of Y₂O₃ or the like is carried out as a surface finishing of the inner wall of the etching processing chamber, causing the sprayed coating to be exposed to the plasma, while serving as the plasma resistance material. For example, this can prevent the sprayed coating from coming off. However, the corrosion of the substrate covered with the sprayed coating was not taken into consideration. In particular, in the etching process using the halogen-based gas, the halogen-based gas may accumulate in the sprayed coating. In cases where the component with its surface thermal-sprayed has been used for a long time, or when the component is washed with pure water, alcohol, or a solvent, the halogen-based gas accumulating in the sprayed coating may reach the substrate, inducing the corrosion of the substrate. Thus, the Y₂O₃ sprayed coating for protecting the substrate from the plasma may peel off.

As mentioned above, in the prior art as disclosed in the above-mentioned JP-A 164354/2001, the reactivity between the inner wall of the etching processing chamber with its surface thermal-sprayed or the inside component within the processing chamber, and the halogen-based gas used in the etching process was not taken into consideration sufficiently.

Particularly, when the aluminum or aluminum alloy is used for the substrate of the inner wall of the etching processing chamber or the like, the halogen-based gas, such as Cl, may be diffused and proceed into the sprayed coating made of the metallic oxide film, such as Y₂O₃, to reach the substrate of the inner wall of the etching processing chamber or the like. In the etching processing chamber, when the substrate of its inner wall or the like is made of aluminum or aluminum alloy, the aluminum or aluminum alloy reacts with the halogen-based gas such as Cl to form a compound, such as Al—Cl or the like. Some Al—Cl compounds sublime to be scattered again in all directions within the etching processing chamber, while others remain on the surface of the substrate. Since the Al—Cl compound is apt to be deposited at an interface surface between the sprayed coating made of a metallic oxide film, such as Y₂O₃, and the substrate coated with the sprayed coating, the corrosion will proceed, causing the sprayed coating to peel off, while the substrate is subjected to corrosion. As a result, a part of the substrate corresponding to a part of the sprayed coating which has peeled off on the inner wall in the etching processing chamber may be exposed to a gas used in the etching process, and subjected to corrosion by the gas, causing a large amount of foreign matter. Furthermore, the foreign matter caused may be deposited on a wafer surface for a semiconductor element in the etching process, thus causing faulty wiring of a semiconductor device or the like, which is manufactured by etching.

Then, in the example disclosed in JP-A 166043/2003, the thickness of alumite coating is 20 to 30 μm. However, if such a thick alumite coating is formed on an aluminum substrate, there is a high possibility that cracks might occur on the surface of the coating. This leads to a problem that the alumite coating and further the aluminum substrate positioned under the coating are damaged by the corrosive gas entering via pores of the sprayed coating or a by-product.

Furthermore, in JP-A 225745/2005, the surface of an alumina substrate (ceramics) is subjected to chemical etching directly, or after being processed by sand blasting in advance to achieve the above-mentioned surface roughness. Even in the structure of the JP-A 225745/2005, the lower layer cannot be prevented from being damaged by the corrosive gas entering the sprayed coating, such as Y₂O₃, or YAG, or by the by-product, as is the case with the example disclosed in the JP-A 164354/2001.

### SUMMARY OF THE INVENTION

The invention has been made in view of the foregoing problems, and it is an object of the invention to provide a plasma etching apparatus which can reduce corrosion of a substrate of an inner wall or the like of an etching processing chamber, thus preventing a sprayed coating from peeling off, while decreasing an amount of foreign matter due to the sprayed coating, and a method for forming an inner wall of a plasma processing chamber.

It is another object of the invention to provide a plasma etching apparatus which can reduce corrosion of an inner wall or the like of an etching processing chamber, due to a halogen-based gas used in an etching process, and a method for forming an inner wall of a plasma processing chamber.

The brief summary of representative embodiments of the invention disclosed herein will be described below.

In one aspect of the invention, a plasma etching apparatus for etching an object to be processed, using a plasma in a processing chamber includes a sprayed coating that covers an inner wall of the processing chamber, the sprayed coating being exposed to the plasma. Also, the plasma etching apparatus includes a barrier film having a thickness of 5 μm or less, and formed between the sprayed coating and a surface of a substrate of the inner wall of the processing chamber, the surface of the substrate being roughened.

In the invention, after roughening the surface of the inner wall member of the etching processing chamber, which involves blast processing, for producing an anchor effect of the sprayed coating, the thin barrier film of 5 μm or less in thickness is disposed by anodic oxidation processing or the like, and onto the thin film is attached the sprayed film made of ceramics or the like having the high resistance to plasma.

Thinning of the barrier film, for example, of the anodic oxide film, can provide the sufficient anchor effect to the sprayed coating even when the sprayed coating is formed on the barrier film, thus preventing the sprayed coating from peeling off. Furthermore, the thinning of the barrier film ensures heat resistance, which does not cause cracks in the barrier film even when the sprayed coating is formed on the barrier film. As a result, even if the halogen-based process gas is diffused and proceeds into the sprayed coating, the barrier film disposed between the sprayed coating and the substrate of the inner wall member of the etching processing chamber prevents the process gas from reaching the substrate.

The barrier film for prevention of corrosion is made of any one of an anodic oxide film, a plating film, a sputtered film, and a chemical vapor deposition (CVD) film when the substrate is made of aluminum or aluminum alloy. When the substrate is made of stainless steel, the barrier film may be any one of the plating film, the sputtered film, and the CVD film.

According to the invention, the sprayed coating covering the inner wall member of the etching processing chamber does not peel off from the substrate due to corrosion. Thus, the invention achieves the object of preventing the sprayed coating from peeling off. That is, this can reduce the occurrence of cracks of the sprayed coating, and hence no part of the sprayed coating is apt to be scattered in all directions and to act as the foreign matter. This results in less damage of the inner wall member of the etching processing chamber by the plasma, and in no scattering of foreign matter over the wafer to be subjected to the etching process or the like, thereby manufacturing devices with few defects effectively.

### BRIEF DESCRIPTION OF THE DRAWINGS

FIG. 1 is a longitudinal sectional view of a plasma etching apparatus according to one preferred embodiment of the invention;

FIG. 2 is a sectional view of an etching processing chamber 100 of the plasma etching apparatus according to the embodiment;

FIG. 3 shows a relationship among the number of wafers processed, a dimension of an etched shape, and a temperature of an earth cover;

FIG. 4 is a sectional view of the earth cover according to the embodiment;

FIG. 5 is an enlarged sectional view of the earth cover according to the embodiment;

FIG. 6 is a sectional view schematically showing a structure of a surface of a member covered with a coating; and

FIG. 7 shows an evaluation result of a temperature at which cracks occurred in an anodic oxide film.

### DETAILED DESCRIPTION OF THE PREFERRED EMBODIMENTS

The invention is directed to prevention of peeling of a sprayed coating which covers an inner wall and/or a surface of an inside component of an etching processing chamber facing a plasma (hereinafter singly referred to as an inner wall of the etching processing chamber, or a processing chamber inner wall).

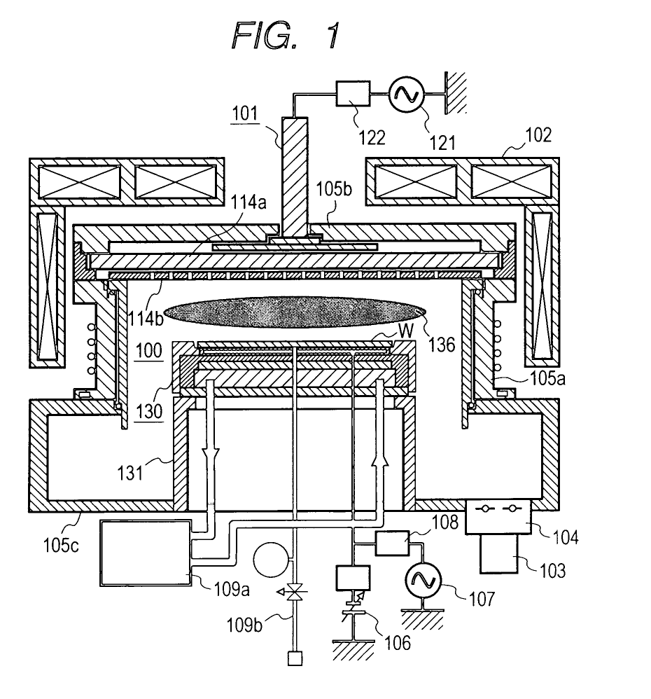

One preferred embodiment of the invention will be described hereinafter with reference to FIGS. 1 to 7.

FIG. 1 is a sectional view of an etching processing apparatus according to the embodiment of the invention. As shown in FIG. 1, the etching processing apparatus includes a processing chamber 100 consisting of housings 105a to 105c provided within a vacuum vessel, an antenna 101 for emitting electromagnetic waves, and a holding stage 130 on which an object to be processed, such as a semiconductor wafer W, is placed within the processing chamber 100. The holding stage 130 is called an “electrostatic attraction electrode”. The antenna 101 is held by the housing 105b constituting a part of the vacuum vessel, and has its end connected to a crystal plate 114a. The crystal plate 114a connected to the antenna 101 constitutes an upper electrode, and is disposed in parallel to and opposed to the holding stage constituting an lower electrode. Around the processing chamber 100, a magnetic field forming means 102 is disposed which includes, for example, a magnetic coil and a yoke. The processing chamber 100 is the vacuum vessel which achieves a vacuum pressure of, for example, 1/10000 Pa by a vacuum exhaust system 103. A process gas for etching the object to be processed, or for performing processing, involving the formation of films, is supplied at a predetermined flow rate and at a prescribed mixing ratio from gas supply means not shown, and then is introduced into the processing chamber 100 via a shower plate 114b. The process gas has its processing pressure controlled within the processing chamber 100 by the vacuum exhaust system 103 connected to the housing 105c and by exhaust adjustment means 104. In general, in most cases, the processing pressure during the etching process is adjusted to a range of 0.1 to 10 Pa for use in the etching processing apparatus.

The other end of the antenna 101 is connected to an antenna power supply 121 via a matching circuit 122. The antenna power supply 121 may supply power having a UHF band frequency of 300 MHz to 1 GHz. In the embodiment, the frequency of the antenna power supply 121 is 450 MHz. The holding stage 130 is connected to a high voltage power supply 106 for electrostatic attraction, and to a bias power supply 107 for supplying bias power of, for example, 200 kHz to 13.56 MHz via a matching circuit 108. Also, the holding stage 130 is connected to a temperature adjustment unit 109a for temperature adjustment, and a heat-transfer gas supply unit 109b. In the embodiment, the frequency of the bias power supply 107 is 2 MHz.

In the etching processing apparatus, with this arrangement, the etching gas introduced into the processing chamber 100 is converted into a plasma (136) efficiently by an interaction between an electric field having a high frequency supplied via the antenna 101, and a magnetic field formed by the magnetic coil. In the etching process, incident energy of ions in the plasma, which are incident on a wafer W, is controlled by a high frequency bias applied to the holding stage 130, thereby providing the desired etched shape.

In the embodiment, parts of the inner wall member of the etching processing chamber 100 except for the shower plate 114b, that is, a cylindrical wall detachably held in the housing 105a of the etching processing chamber 100, the housing 105c, a cover 131 around the lower part of the holding stage 130, and a wall surface of another component exposed to the plasma and disposed in the etching processing chamber are hereinafter referred to as the simple “inner wall of the etching processing chamber”.

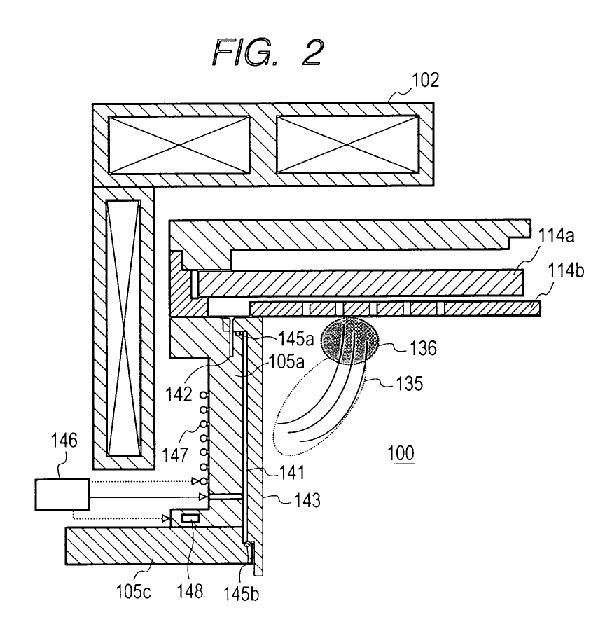

Now, the structure of the inner wall of the etching processing chamber 100 will be described in detail. FIG. 2 shows a detailed sectional view of the etching processing chamber 100 of the embodiment. The processing chamber 100 mainly comprises a cylindrical chamber 105a having an inner diameter of 600 mm and made of aluminum alloy, a cylindrical earth cover 143 detachably held within the cylindrical chamber 105a and engaged with the cylindrical chamber 105a by a bolt 142, the crystal plate 114a of 25 mm in thickness made of a crystal disk, and the disk-shaped shower plate 114b disposed directly below the crystal plate 114a.

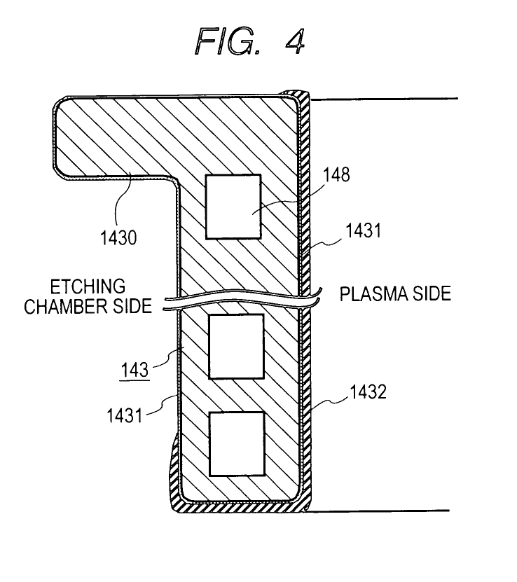

As illustrated in FIG. 4, on a surface of a substrate 1430 of the earth cover 143 which is exposed to the plasma, is formed a sprayed coating 1432 by thermal spraying Y₂O₃ having a purity of 99.9% in a thickness of 0.01 mm or more. On the entire surfaces of the substrate 1430, an anodic oxide film 1431 is formed. This anodic oxide film 1431 on the surface is obtained by performing the anodic oxidation processing on the entire surfaces of the substrate 1430 to form a coating up to a prescribed thickness. The processed anodic oxide film 1431 is exposed as a surface of the earth cover 143 on parts other than the sprayed coating 1432. The material for the sprayed coating may be selected from ceramic materials having excellent plasma resistance, including YF₃, and Yb₂O₃ as well as Y₂O₃.

Returning now to FIG. 2, the earth cover 143 and the chamber 105a are sealed with O rings 145a and 145b, and a helium gas is supplied to a gap 141 between the cover and the chamber by a temperature adjustment device 146 (pressure: about 1000 Pa). A heater 147 for the temperature adjustment is disposed on an outer peripheral surface of the chamber 105a, and a flow path 148 through which a refrigerant for the temperature adjustment circulates is formed in the lower part of the chamber 105a. The refrigerants circulating through the heater 147 and the flow path 148 are also controlled by the temperature adjustment device 146. Note that a member having excellent thermal conductivity (for example, aluminum nitride) maybe sandwiched in the gap 141 between the earth cover 143 and the chamber 105a engaged by the bolt 142. In the processing chamber with this type of shape, the earth cover 143 is individual from the chamber 105a, thus facilitating replacement of the earth cover 143, as well as cleaning and maintenance thereof.

As will be described later, in the embodiment, any one of the earth cover 143, the lower housing 105c, and the stage cover 131 disposed around the lower part of the holding stage 130 has its aluminum substrate surface covered with the barrier film serving as the inner wall of the etching processing chamber. In addition, on the barrier film is formed the sprayed coating made of ceramic material having excellent plasma resistance, such as YF₃, Yb₂O₃, and Y₂O₃.

In the etching processing apparatus disclosed in the embodiment, magnetic lines of force 135 as shown in FIG. 2 are formed by the magnetic field forming means 102 consisting of the magnetic coil and the yoke. The high density plasma 136 is produced directly below the shower plate 114b by the high frequency applied by the antenna, and by the magnetic lines of force 135 caused by the magnetic coil and yoke. The plasma produced is constrained by the magnetic lines of force 135, resulting in increased density of plasma on the surface of the earth cover 143, which is positioned on an extended line of the magnetic lines of force 135. At this time, in the etching processing apparatus, a bias power supply for supplying bias power, the holding stage 130, the plasma 136, and the surface of the earth cover 143 form an electric circuit, in which the surface of the earth cover having the high plasma density is a ground plane. On the surface of the earth cover 143, which is the ground plane, electrons in the plasma move at high speeds, so that a stable electric field, namely, an ion sheath is caused by the stranded ions. Since the ions in the plasma are incident on the surface of the earth cover 143 by the ion sheath (by the electric field), the earth cover 143 is heated, whereby the coating formed on the earth cover 143 is also heated. In the earth cover 143, conventionally, there is fear that the sprayed coating may peel off due to a difference in expansion rate between the aluminum substrate and the sprayed coating covering the aluminum substrate, leading to the occurrence of foreign matter.

Since it is difficult to completely fill the sprayed coating covering the surface of the earth cover 143 with the thermal spraying material, certain pores are held in the sprayed coating. Into the pores of the sprayed coating, a halogen-based process gas to be used in the etching process enters readily. The process gas entering the sprayed coating is diffused through the pores of the sprayed coating and proceeds to reach the substrate. In this case, the etching processing chamber and etching processing chamber inside component made of aluminum alloy whose surfaces in contact with the plasma are covered with the sprayed coating may be subjected to corrosion between the sprayed coating and the aluminum substrate.

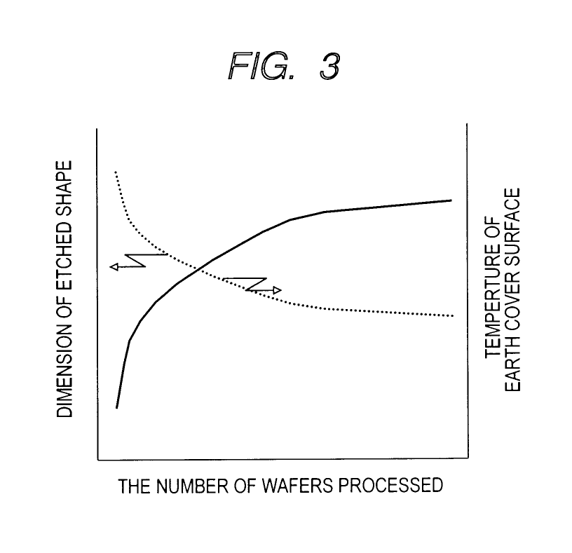

In the etching processing apparatus, it is important to render the change in temperature of the wall of the processing chamber small so as to stabilize the etching property. FIG. 3 illustrates the relationship among the number of wafers processed, the dimension of the etched shape, and the temperature of the earth cover. The etched shape as shown in the figure indicates the dimension of a clearance between grooves of an etched part. The figure shows that the dimension is stabilized with increasing the number of wafers etched. In contrast, it shows that the temperature of the earth cover is enhanced with increasing the number of wafers processed. The reason why the dimension of the etched shape is changed is that reactions of out gas (such as water) emitted from the surface of the earth cover, or of radicals on the earth cover surface differ mainly depending on the temperature of the earth cover. Therefore, it is very important to hold the temperature of the wall of the earth cover in the etching processing apparatus. After considering these facts, it is concluded that the temperature of the earth cover may preferably 100° C. or more taking into consideration emission of water or the like.

In the etching processing apparatus of the embodiment as described above, the earth cover 143 before the etching process or the like is controlled to have a predetermined temperature by the heater 147, especially, controlled to have the predetermined temperature by heat input from the plasma and refrigerant during the etching process. The invention is not limited to this temperature adjustment mechanism. Alternatively, the temperature adjustment mechanism may provide a refrigerant path in the earth cover, through which the refrigerant may be flown to be managed to a predetermined temperature, as shown in FIG. 4, for example. It is ascertained that when the antenna power is about 1000 W, the bias power is 500 W, and the temperature of the refrigerant is set to about 80° C., the temperature of the earth cover can be held about 120° C. Furthermore, when the gas (for example, air and nitrogen) is flown, the temperature of the earth cover is raised to a predetermined temperature by aging processing, and when the predetermined temperature is reached, the gas may be flown into.

Generally, in the etching processing apparatus, aluminum alloy is applied to the component constituting the processing chamber, and anodic oxidation processing (aluminum alumite, Al₂O₃) is formed on the surface of the component in contact with the plasma. When more resistance to plasma is required, in addition to carrying out the anodic oxide film processing, the sprayed coating made of ceramics or the like and having excellent resistance to plasma is generally formed on the surface of the plasma processing chamber. The sprayed coating formed on the surface of the plasma processing chamber has a layered structure because semisolid metal particles are stuck to and layered on the surface of the member to be thermal-sprayed, at high speed. Thus, in order to prevent adsorption of water into a boundary (void) between the substrate, and the coating and the inner part thereof, the processing for filling in the void (hole sealing processing) is carried out. In the etching processing apparatus, such a coating is formed to ensure long-term stability. When cracks occur in the coating, the plasma property is changed, resulting in variation in etched shape. In addition to the etching property, contact and reaction of the substrate of the crack tip (aluminum alloy) with the process gas in the plasma may cause sources of foreign matter. The halogen-based process gas is diffused and proceeds into the sprayed coating in the etching process to reach the aluminum substrate. This corrodes the aluminum substrate, causing the cracks in the sprayed coating. If the etching processing chamber is exposed to air while the aluminum substrate is corroded, a halogen compound of the corroded aluminum absorbs water in air to have its volume expanded, whereby the sprayed coating covering the aluminum substrate may peel off. Thus, in order to decrease the amount of foreign matter in the etching processing apparatus, it is important to reduce the occurrence of cracks in the sprayed coating. It is also important to dispose the anodic oxide film such that the halogen-based process gas diffused and proceeding into the sprayed coating is not brought into contact with the aluminum alloy substrate.

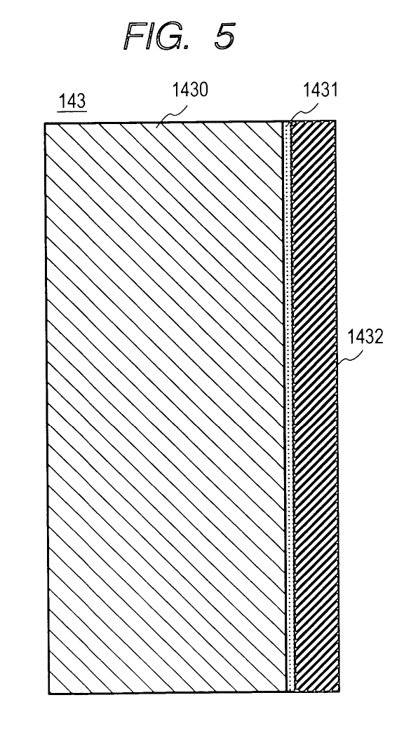

FIG. 4 schematically shows the earth cover according to the embodiment, and FIG. 5 shows an enlarged view of the earth cover according to the embodiment. Since the occurrence of cracks or the like in the anodic oxide film between the aluminum substrate and the sprayed coating may corrode the aluminum substrate, it is important not to cause the cracks in the anodic oxide film.

The stage cover and the lower housing have the same problems. Reference will now be made to how the invention will solve the foregoing problems by taking the earth cover as one example.

As shown in FIG. 5, the surface of the aluminum substrate 1430 constituting the inner wall member of the processing chamber has the average surface roughness of 5 to 10 μm. On the surface of the substrate is formed the barrier film 1431 made of an anodic oxide film or alumite and having the average surface roughness of not less than 0.1 μm nor more than 5 μm. On this barrier film, the ceramic sprayed coating 1432 is formed as the member having the resistance to plasma. This sprayed coating serves as the surface of the inner wall member which will come into contact with the plasma.

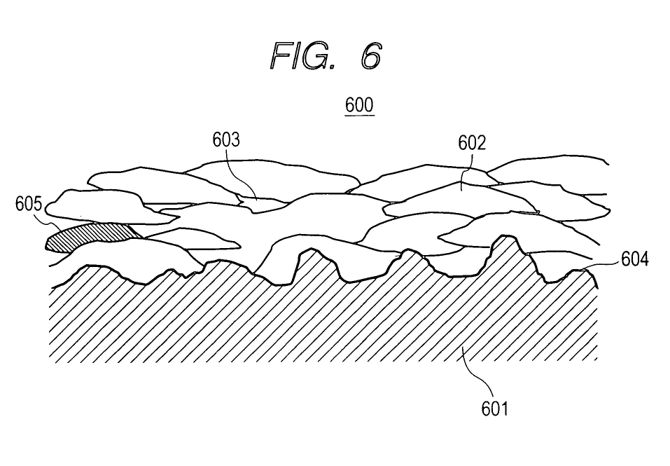

Using FIG. 6, the structure of the surface of the member with the sprayed coating formed thereon will be described below. FIG. 6 is a sectional view schematically showing the structure of the surface of the member with the sprayed coating formed thereon. In this figure, a member surface 600 is a surface of a sprayed coating formed on a member made of alloy material having electrical conductivity, such as aluminum, and serving as a base material 601. The surface of the base material 601 has an appropriate surface roughness. Such surface roughness is achieved so as to strengthen a connection between the surface and sprayed particles made of coating material and thermal sprayed. The average surface roughness Ra is generally in a range of 5 to 10 μm.

As shown in FIG. 6, the sprayed coating 604, which is thermal sprayed, is formed by superimposing a plurality of flat punctured sprayed particles 602 on one another, while displacing positions thereof from one another. Among these plurality of sprayed particles 602, pores 603 and inclusions 605 such as oxide exist. The corrosive gas included in the process gas and particles of active substance excited by the plasma burrow their way into the pores 603, causing corrosion and degradation of the sprayed coating 602 due to combination with the coating. On the other hand, the presence of pits and projections based on the surface roughness of the base material 601 causes the sprayed particles 602 to burrow their way into the pits, or the tip ends of projections to become embedded into the particles 602. This leads to a mechanical connection between the sprayed particles 602 and the base material 601.

Generally, it is considered that the adhesion of the sprayed coating 604 to the base material 601 depends on a combined effect of the mechanical connection (anchor effect) between the pits/projections on the surface of the base material 601 and the sprayed particles 602, a metallurgical connection, and a physical connection or the like due to intermolecular attraction such as Van der Waals attraction. As can be seen in the embodiment, it is anticipated that the connection between the base material 601 and the sprayed particles 602 is based on the anchor effect when the base material 601 is made of aluminum alloy, and the material for thermal spraying is a ceramic material.

As mentioned above, once large corrosive particles or active particles burrow their way into the pores 603 in the sprayed coating 604, or into a boundary between the sprayed particles 602, degradation of the sprayed coating 604 proceeds, leading to corrosion or degradation of the base material 601. To avoid this, when another coating is disposed as another member between the sprayed coating 604 and the surface of the base material 601 made of aluminum alloy, it is necessary that the surface of this another coating as another member has pits and projections so as not to lose the anchor effect, which is the mechanical connection with the sprayed coating. Once the anchor effect is lost, even when the surface is coated with another member, the sprayed coating 604 may peel off or be damaged, whereby a large area may be exposed to the corrosive particles.

In the embodiment, on the surface of the substrate constituting the earth cover is formed the barrier film made of a thin anodic oxide film, for example, an alumite film when the base material is aluminum alloy. On the barrier film, the sprayed coating is formed, thereby ensuring the above-mentioned anchor effect. Note that when the coating is formed on the surface of the base material 601 by anodic oxidation, the coating tends to become thinner on the protrusions according to the surface roughness of the base material 601, while it tends to become thicker on the pits. The inventors have found that the thicker the anodic oxide film, the smaller the pits and projections of the coating, and the surface roughness thereof. Also, the inventors have found that the anodic oxide film should be formed to have a thickness of 5 μm or less, and 0.1 μm or more so as not to reduce the anchor effect more than necessary. The examples according to the invention are envisaged based on the above-mentioned findings.

That is, when the ceramics is thermal sprayed on the aluminum alloy, the surface of the base material is normally roughened by the blast processing or the like to have a surface roughness Ra of 5 to 10 μm. However, in such a case as the embodiment, if the surface of the aluminum base material having this roughness is processed and subjected to anodic oxide film processing so as to have an effect of corrosion prevention of aluminum alloy, the coating or film formed on the base material surface may become thinner on protrusions of the base material, but thicker on pits thereof. Thus, in order to maintain the surface roughness Ra of 5 to 10 μm, the thickness of the anodic oxide film should be 0.1 to 5.0 μm.

Accordingly, in the embodiment, the thin corrosion prevention layer is disposed as the barrier layer between the sprayed coating and the substrate of the inner wall of the etching processing chamber, for example, the earth cover. Thus, even if the halogen-based process gas used in the etching process is diffused and proceeds into the sprayed coating covering the surface of the inner wall of the etching processing chamber, the proceeding of the gas is terminated by the barrier film, so that the gas can be prevented from reaching the inner wall of the etching processing chamber.

In particular, the formation of the anodic oxide film of 5 μm or less in thickness as the barrier film disposed between the aluminum substrate of the inner wall of the chamber and the sprayed coating in contact with the plasma does not generate cracks in the barrier film due to thermal shock or shock of ceramic particles when carrying out the thermal spraying on the inner wall of the etching processing chamber, with no peeling of the barrier film. If the anodic oxide film is heated to 250° C. or more, no cracks will occur. The barrier film is formed after the inner wall of the etching processing chamber is roughed by the blast processing, the grinding processing, or the polishing processing. Since the barrier film is thin, for example, of 0.1 to 5 μm in thickness, a surface condition of the barrier film formed can reflect the roughened surface condition of the inner wall, resulting in enhanced adhesion of the sprayed film to the etching processing chamber inner wall.

According to the embodiment, in the sprayed coating disposed above the inner wall of the etching processing chamber in the plasma etching apparatus using a halogen-based process gas, the halogen-based process gas entering the pores of the sprayed coating can be prevented from reaching and corroding the substrate, so that the sprayed coating may not peel off. As a result, foreign matter due to the sprayed coating in the etching processing chamber, or foreign matter due to the substrate does not occur.

This can decrease the amount of foreign matter or pollutants on a wafer to be etched, resulting in low defective rate of the wafers etched.

The positioning of the barrier film between the aluminum or aluminum alloy substrate of the inner wall of the etching processing chamber, and the sprayed coating in contact with the plasma can improve productivity of the etching apparatus itself.

Furthermore, when the refrigerant passes through the refrigerant path in the earth cover, and the temperature of the earth cover is controlled to be held a predetermined value, for example, about 120° C., the possibility of peeling of the sprayed coating due to thermal stress applied to the inner wall and inside component of the etching processing chamber is further decreased.

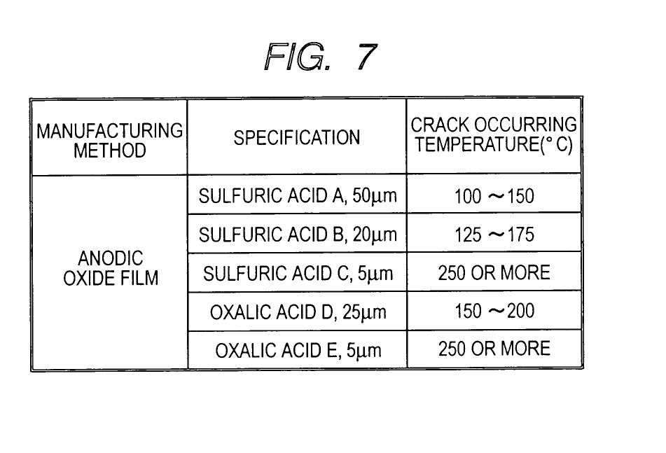

Next, the occurrence of cracks in the coating will be explained in detail. In the embodiment, several general kinds (A to E) of alumite films of 5 to 50 μm in thickness formed on the aluminum substrate (sulfuric acid, oxalic acid) were evaluated for heat-resistant temperature. In experiments, a sample coating was formed on a surface of an aluminum sample material having a dimension of 20 mm×20 mm (thickness 5 mm). Then, while being heated on a hot plate, which enables temperature adjustment with high accuracy, the sample material was examined for the occurrence of cracks on its surface using a microscope. The results were shown in FIG. 7. As shown in FIG. 7, regardless of the kinds of anodic oxide films, the anodic oxide film having a thickness of 5 μm or less did not cause cracks even when the aluminum substrate was heated to a high temperature of 250° C. or more. Thus, the thickness of the anodic oxide film was 5 μm or less, and a ceramic coating with excellent resistance to plasma was thermal sprayed on the film. This prevents cracks from occurring in the sprayed coating which covers the surfaces of the plasma processing chamber, and of the inside component thereof. Providing the anodic oxide film without cracks between the sprayed coating and the aluminum substrate can prevent the process gas proceeding into the sprayed coating by diffusion from coming into contact with the substrate made of aluminum or the like, thereby providing the plasma apparatus having the high stability of etching property or the like.

What is claimed is:

1. A plasma etching apparatus for etching an object to be processed, using a plasma in a processing chamber, the etching apparatus comprising:
a sprayed coating that covers an inner wall of the processing chamber, the sprayed coating being exposed to the plasma; and
a barrier film formed between the sprayed coating and a surface of a substrate of the inner wall of the processing chamber, the surface of the substrate being roughened, the barrier film having a thickness of 5 μm or less.

2. The plasma etching apparatus according to claim 1, wherein the roughened surface of the substrate has an average surface roughness of 5 to 10 μm.

3. The plasma etching apparatus according to claim 1, wherein the substrate is made of aluminum or aluminum alloy, and an alumite layer is formed as said barrier film on the surface of the substrate.

4. The plasma etching apparatus according to claim 1, wherein said substrate is made of a stainless steel, and said barrier film is any one of a plating film, a sputtered film, and a chemical vapor deposition (CVD) film.

5. The plasma etching apparatus according to claim 1, wherein said substrate is made of crystal.

6. The plasma etching apparatus according to claim 1, wherein the sprayed coating is made of one or more kinds of materials selected from the group consisting of Y₂O₃, Gd₂O₃, Yb₂O₃, and YF₃.

7. The plasma etching apparatus according to claim 3, wherein said barrier film has a thickness of 0.1 to 5 μm, and the sprayed coating is made of Y₂O₃ or YF₃.

8. A plasma etching apparatus for etching an object to be processed, using a plasma in a processing chamber,
the processing chamber including a cylindrical chamber made of aluminum or aluminum alloy for constituting a side wall of the chamber, and a cylindrical earth cover detachably held within the cylindrical chamber,
wherein a substrate constituting the earth cover is made of aluminum or aluminum alloy,
the earth cover comprises an alumite layer formed on a surface of the substrate roughened, the alumite layer having a thickness of 5 μm or less, and a sprayed coating made of a member having resistance to the plasma and formed on the alumite layer, and
the earth cover is detachably held within the cylindrical chamber,
the plasma etching processing apparatus comprising means for supplying a gas for temperature adjustment to a gap between the earth cover and the cylindrical chamber.

9. The plasma etching apparatus according to claim 8, wherein the earth cover has an entire surface of the substrate thereof covered with the alumite layer, and wherein the alumite layer of 0.1 to 5 μm in thickness, and the sprayed coating made of said plasma resistance member are formed in an area of the earth cover facing the plasma within the processing chamber.

10. A method for forming an inner wall of a plasma processing chamber in a plasma etching apparatus for etching an object to be processed, using a plasma in the processing chamber, the method comprising the steps of:
roughening a surface of a substrate of the inner wall of said processing chamber;
forming a barrier film of 5 μm or less in thickness on the roughened surface of the substrate of the inner wall of the processing chamber; and
forming a sprayed coating having resistance to plasma on the barrier film.

11. The method according to claim 10, wherein, after the surface of the substrate is roughened to an average surface roughness of 5 to 10 μm by blast processing or grinding processing, the barrier film is formed on the surface of the substrate by any one of methods including plating, anodic oxidation, chemical vapor deposition (CVD), and physical vapor deposition (PVD).

12. The method according to claim 10, wherein the substrate is made of aluminum or aluminum alloy, an anodic oxide film of 0.1 to 5 μm in thickness is formed as the barrier film, and the sprayed coating is made of one or more kinds of materials selected from the group consisting of Y₂O₃, Gd₂O₃, Yb₂O₃, and YF₃.
